(19) United States
(12) Patent Application Publication
(10) Pub. No.: US 2005/0104214 A1
(43) Pub. Date: May 19, 2005

(54) Flexible metal stacked body

(75) Inventors: Akihiro Maeda, Shizuoka-shi (JP); Ichirou Koyano, Shizuoka-shi (JP); Yuusuke Suzuki, Shida-gun (JP); Ken Yoshioka, Shizuoka-shi (JP)

Correspondence Address: WOOD, HERRON & EVANS, LLP, 2700 CAREW TOWER, 441 VINE STREET, CINCINNATI, OH, 45202, US

(73) Assignee: Tomoegawa Paper Co., Ltd., Tokyo (JP)

(21) Appl. No.: 10/987,134

(22) Filed: Nov. 12, 2004

(30) Foreign Application Priority Data
Nov. 13, 2003 (JP) 2003-384217

(51) Int. Cl. H01L 23/48

(52) U.S. Cl. 257/747; 257/748

(57) ABSTRACT

A flexible metal stacked body includes: a metal layer; and a resin stacked body formed on the metal layer, in which the resin stacked body includes at least one thermosetting resin layer and at least one thermoplastic resin layer, one of the at least one thermosetting resin layer is provided adjacent to the metal layer, and the at least one thermosetting resin layer and the at least one thermoplastic resin layer are stacked alternately.

### BACKGROUND OF THE INVENTION

1. Field of the Invention

The present invention related to a flexible metal stacked body having excellent thermostability which is suitable for an electronic device requiring excellent thermostability, particularly a semiconductor integrated circuit device which comprises an insulating layer and a conductor circuit.

Priority is claimed on Japanese Patent Application No. 2003-384217, filed Nov. 13, 2003, the content of which is incorporated herein by reference.

2. Description of Related Art

In recent years, as the reduction in size and width of and the multi-functionality of electronic apparatuses advance, many new high-density mounting technologies have been developed and marketed in order to meet this demand. In view of this background, both requirements regarding reliability of components used in electronic apparatuses, such as optimizing physical properties to conform with diversified mounting technologies, and requirements regarding workability of such components, such as optimizing working conditions, need to be satisfied. For example, the TCP (tape carrier package) method which has been used for some of interposers which are used for semiconductor integrated circuits (ICs) for driving LCDs and for bonding between semiconductor integrated circuits and electric wiring is shifting to fine-pitch scale. As a mounting technique which is compatible with fine-pitch scale, flip-chip bonding is proposed in which IC chips and flexible printed circuit boards are bonded This bonding technique is typically carried out under a high temperature and high pressure condition, and in recent years, a demand for realizing both thermostability and an excellent workability at low temperatures at low cost has become even stronger.

As a metal stacked body used in this flip-chip bonding technique, for example, a stacked body which is fabricated by heat sealing between a stacked body comprising a metal layer, a thermoplastic polyimide layer, a non-thermoplastic polyimide layer and a thermoplastic polyimide layer, and a stacked body comprising a thermoplastic polyimide layer, a non-thermoplastic polyimide layer and a thermoplastic polyimide layer (see Japanese Unexamined Patent Application No. H11-291392, for example) is known. Also, a stacked body comprising a thermoplastic polyimide layer, a non-thermoplastic polyimide layer, a thermoplastic polyimide layer and a metal layer (see Japanese Unexamined Patent Application No. H02-168694, for example) are known. However, these stacked bodies have a drawback in that in order to use a thermoplastic polyimide resin having a high glass-transition temperature required for the flip-chip bonding technique, high temperatures above the glass-transition temperature are required since the resin is insoluble in solvent and requires a high working temperature. Furthermore, a resin having a high glass-transition temperature requires a high thermal history for bonding the resin to an object to be bonded using the heat seal method, and residual stress between the attached layers tends to cause a curl in the stacked body; thus the dimensional change of the stacked body become significant. Although other methods are proposed in which a polyimide precursor is stacked directly to an object to be bonded or the polyimide precursor is applied to a supporting body, it is difficult to fabricate products at a stable manner since imidization of the polyimide precursor requires a high thermal history, expensive facilities and controlling technologies.

### SUMMARY OF THE INVENTION

The present invention provides a reliable and low-cost flexible metal stacked body which exhibits excellent thermostability, low curl characteristic, and an excellent workability at low temperatures.

The present invention is directed to a flexible metal stacked body including: a metal layer; and a resin stacked body formed on the metal layer, wherein the resin stacked body includes at least one thermosetting resin layer and at least one thermoplastic resin layer, one of the at least one thermosetting resin layer is provided adjacent to the metal layer, and the at least one thermosetting resin layer and the at least one thermoplastic resin layer are stacked alternately. This flexible metal stacked body can improve thermostability of the resin stacked body in which all of the resin layers are stacked on the metal layer, and reduce curls and the dimensional change.

The present invention makes it possible to provide a flexible metal stacked body which exhibits excellent thermostability, low curl characteristic and an excellent workability at low temperatures, and can be manufactured at low cost. The present invention is particularly useful in a flexible printed circuit board which is suitable for a semiconductor integrated circuit (IC) comprising an insulating layer and a conductor circuit. Furthermore, the present invention can provide a flexible metal stacked body which can be used for a flip-chip bonding which is compatible with fine-pitch scale.

### BRIEF DESCRIPTION OF THE DRAWINGS

FIG. 1 is a cross-sectional view of a flexible metal stacked body according to one embodiment of the present invention.

### DETAILED DESCRIPTION OF THE INVENTION

In the following, the present invention will be described in detail.

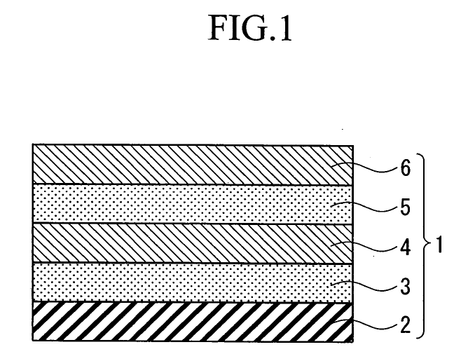

Referring to FIG. 1, a cross-sectional view of a flexible metal stacked body according to the present invention is shown. A flexible metal stacked body 1 of the present invention comprises a first thermosetting resin layer 3, a first thermoplastic resin layer 4, a second thermosetting resin layer 5, and a second thermoplastic resin layer 6 which are stacked on one side of a metal layer 2 in order from the bottom to top, and the thermosetting resin layers and the thermoplastic resin layers are stacked alternately. Hereinafter, any resin stacked body comprising one or more thermosetting resin layers and one or more thermoplastic resin layers stacked over a metal layer is called a resin stacked body. However, any number of the thermosetting resin layers and any number of the thermoplastic resin layers may be included in the resin stacked body. For example, a three-layered structure comprising a metal layer, a thermosetting resin layer and a thermoplastic resin layer, or a four-layered structure comprising a metal layer, a thermosetting resin layer, a thermoplastic resin layer and a thermosetting resin layer, or a six-layered structure comprising a metal layer, a thermosetting resin layer, a thermoplastic resin layer, a thermosetting resin layer, a thermoplastic resin layer and a thermosetting resin layer, or a seven-layered structure comprising a metal layer, a thermosetting resin layer, a thermoplastic resin layer, a thermosetting resin layer, a thermoplastic resin layer, a thermosetting resin layer and a thermoplastic resin layer are possible. Among them, a five-layered structure shown in FIG. 1 is particularly preferable. This is because a stacked body comprising four or fewer layers can maintain excellent thermostability but does not have sufficient effects of reducing curls and the dimensional change, and a stacked body comprising six or more layers can decrease dimensional change but has a smaller effect of retaining excellent thermostability.

In the flexible metal stacked body according to the present invention, the ratio of the thickness of the thermosetting resin layer adjacent to the metal layer to the thickness of the thermoplastic resin layer adjacent to this thermosetting resin layer (T_{α}/T_{β}) preferably ranges from 0.15 to 1, and more preferably ranges from 0.3 to 1 when T_{α} is the thickness of the thermosetting resin layer adjacent to the metal layer and T_{β} is the thickness of the thermoplastic resin layer adjacent to this thermosetting resin layer. More specifically, the ratio (T_{α}/T_{β}) in the range from 0.15 to 1 means that the thickness of the first thermosetting resin layer 3 adjacent to the metal layer (T_{α}) to the thickness of the first thermoplastic resin layer 4 adjacent to the first thermosetting resin layer 3 (T_{β}) shown in FIG. 1 ranges from 0.15 to 1. If T_{α}/T_{β} is more than 1, the effect of reducing curls and the dimensional change is difficult to obtain satisfactorily, and flexibility, tensile strength, tear strength and the like tend to be compromised in the entire stacked body when a thermoplastic resin layer is stacked on a thermosetting resin layer. If T_{α}/T_{β} is less than 0.15, the effects of reducing deformity and retaining thermostability are difficult to obtain satisfactorily when a thermoplastic resin layer is stacked on a thermosetting resin layer. The thickness of the thermosetting resin layer adjacent to the metal layer (the first thermosetting resin layer 3 in FIG. 1) preferably ranges from 3 μm to 15 μm, and more preferably ranges from 5 μm to 10 μm. The thickness of the thermoplastic resin layer adjacent to this thermosetting resin layer (the first thermoplastic resin layer 4 in FIG. 1) preferably ranges from 5 μm to 40 μm, and more preferably ranges from 5 μm to 20 μm. The thickness of the thermosetting resin layer adjacent to this thermoplastic resin layer (the second thermosetting resin layer 5 in FIG. 1) preferably ranges from 3 μm to 15 μm, and more preferably ranges from 5 μm to 10 μm. The thickness of the thermoplastic resin layer adjacent to this thermosetting resin layer (the second thermoplastic resin layer 6 in FIG. 1) preferably ranges from 5 μm to 40 μm, and more preferably ranges from 5 μm to 20 μm.

It should be noted that the ratio T_{α}/T_{β} preferably ranges from 0.15 to 1 when T_{α} is the thickness of the second thermosetting resin layer 5 in FIG. 1, and T_{β} is the thickness of the second thermoplastic resin layer 6. T_{α}/T_{β} in the range from 0.3 to 1 is more preferable since T_{α}/T_{β} in this range can provide the effects of reducing curls and the dimensional change, as well as the effect of retaining thermostability.

It should be noted that the thickness of each resin layer can be measured by the following procedure. The metal layer is removed using an etching solution and the like to obtain the resin stacked body without the metal layer and the thickness of the stacked body is measured. Then the thickness of the thermosetting resin layer is measured using a micrometer and the like after removing the thermoplastic resin layer using a solvent and the like to obtain the thermosetting resin layer without the thermoplastic resin layer.

The penetration measured by a TMA (thermo-mechanical analyzer) of the resin stacked body of the present invention is preferably 10 μm or less, and more preferably 8 μm or less, and even more preferably 5 μm or less. The term “penetration measured by TMA” is a displacement at 300° C. of the resin stacked body which has been removed the metal layer using a thermo-mechanical analyzer (TMA) when compressing the surface to which the metal layer had been adhered to using a penetration prove having a tip size of 100 μm×100 μm. Other measurement conditions are as follows: load of 1000 mN/cm², the rate of temperature rise of 50° C./min, and the environmental condition of normal temperature and normal humidity. If the penetration measured by TMA of the resin stacked body is more than 10 μm, the deformation of the thermosetting resin layer adjacent to the metal layer will be significant when subjected to a thermal history, which makes a bonding between an IC chip and a flexible printed circuit board, such as a flip-chip bonding, difficult to achieve. Preferably, the penetration measured by TMA of the thermosetting resin layer is 5 μm or less and more preferably 4 μm or less, and is smaller than the penetration measured by TMA of the thermoplastic resin layer. If the penetration of the thermosetting resin layer is 5 μm or greater, the deformation of the thermosetting resin layer adjacent to the metal layer is significant when subjected to a thermal history, which makes a bonding between an IC chip and a flexible printed circuit board, such as a flip-chip bonding, difficult to achieve. Furthermore, the ratio of the penetration (dA/dB) of the thermoplastic resin layer (dB) to the penetration of the thermosetting resin layer (dA) measured by TMA preferably ranges from 0.1 to 0.9, and more preferably ranges from 0.2 to 0.8. If the ratio of displacement is less than 0.2, melting and deformation of the thermoplastic resin layer cannot be prevented completely by the thermosetting resin layer and the effect of retaining thermostability is difficult to achieve. If the ratio is greater than 0.8, the effect of improving thermostability achieved by stacking a thermosetting resin is difficult to obtain. It should be noted a resin stacked body without the metal layer can be obtained by removing the metal layer using an etching solution and the like.

The thermosetting resin layer according to the present invention preferably has a higher glass-transition temperature (Tg) and thermal decomposition temperature than the thermoplastic resin layer, and preferably exhibits greater elastic modulus (E′) and loss elastic modulus (E″) in the dynamic viscoelasticity measurement. Specifically, in the dynamic viscoelasticity measurement using a compulsion vibration dissonance viscoelasticity tester (Rheovibron from Orientech Co., Ltd.), the elastic modulus (E′) of the thermosetting resin layer at 350° C. is preferably higher than the elastic modulus (E′) of the thermoplastic resin layer at 350° C. by 200 MPa, and more preferably by 500 MPa. A non-limiting preferable example of conditions of the dynamic viscoelasticity measurement are a vibration frequency of 11 MHz, a static tension of 3.0 gf, a sample size of 0.5 mm (width)×30 mm (length), and a rate of temperature rise of 10° C./min, and the environmental condition of normal temperature and normal humidity. If the above-described relationship between the dynamic viscoelasticity values is satisfied, thermostability of the thermosetting resin layer is higher than that of thermoplastic resin layer and the stacked body retains excellent thermostability. Therefore, when the resin layers are subjected to a thermal history from the metal layer side, deformation in the resin layers due to melting or liquidization at the surface of the resin can be reduced. Furthermore, by alternately stacking one or more thermosetting resin layers and one or more thermoplastic resin layers on a metal layer, a flexible metal stacked body exhibiting less curls and the dimensional change while retaining excellent thermostability can be obtained. The reason why curls and the dimensional change are contained at low level while retaining excellent thermostability is not clear, but it is hypothesized that thermoplastic resin layers which are provided adjacent to each thermosetting resin layer absorb stress caused by a desolvation agent when layers are stacked and reduce shrinkage due to curing of the thermosetting resin layers; thus a stacked body with low curls and dimensional change can be obtained. Thus, even when electrodes of an IC chip and a conductor comprising the metal layer of the flexible metal stacked body are bonded together under a high temperature and high pressure condition, as in the case of the flip-chip bonding technique, deformation and melting of the resin layers can be suppressed since the resin layer which is in contact with the metal layer has excellent thermostability. Furthermore, the flexible stacked body exhibits low curls and dimensional change, which makes the flexible stacked body suitable for fine-pitch scales which have been demanded in recent years.

It should be noted that if a thermoplastic resin layer is stacked adjacent to the metal layer and then a thermosetting resin layer is stacked on the thermoplastic resin layer to form a flexible metal stacked body, the effect of improving the thermostability of the entire resin cannot be achieved since the thermoplastic resin layer which is in contact with metal layer has a low thermostability. Furthermore, if a thermosetting resin layer is stacked adjacent to the metal layer and then two thermoplastic resin layers are stacked on the thermosetting resin layer to form a flexible metal in which the thermosetting resin layer and the thermoplastic resin layers are not stacked alternately, the effect of improving the thermostability cannot be achieved since deformation of the two stacked thermoplastic resin layer due to melting or liquidization becomes significant. It should be noted that the flexible metal stacked body according to the present invention may be a metal stacked body in which a circuit is provided on the metal layer.

Non-limiting examples of the metal layer of the flexible metal stacked body according to the present invention may be a metal foil or a metal plate made of gold, silver, copper, phosphor bronze, iron, nickel, stainless steel, titanium, aluminum or alloy of the above-mentioned metals. Among them, the metal layer is preferably one metal foil selected from the group consisting of a copper foil, a stainless steel foil, an aluminum foil, and a steel foil. The thickness of the metal layer is not limited, but the metal layer preferably is a metal foil having a thickness ranging from 3 μm to 50 μm, and more preferably ranging from 5 μm to 35 μm.

The thermosetting resin contained in the thermosetting resin layer of the present invention is a resin composition which cures by heat treatment and becomes insoluble and infusible, and a three-dimensional cross-linked thermosetting resin is suitable for use. A three-dimensional cross-linked thermosetting resin is a resin having a reactive functional group which can form a three-dimensional cross-linking or net structure to polymerize with other functional groups, and preferably has at least two reactive functional groups in one molecule. Examples of such a functional group include epoxy groups, phenolic hydroxy groups, alcoholic hydroxy groups, thiol groups, a carboxyl group, amino groups, and isocyanate groups. Preferable functional groups are functional groups having a carbon-carbon double bond such as allyl groups, vinyl groups, acrylic groups, and methacryl groups, or an acetylene carbon-carbon triple bond. More preferable compounds are compounds having an active functional group which can cause an intra-molecular or inter-molecular en reaction or Diels-Alder reaction, such as maleimide derivatives, bis-allyl-nadi-imide derivatives, allyl phenol derivatives, isocyanurate derivatives, and at least one compound selected from the group consisting of maleimide derivatives, bis-allyl-nadi-imide derivatives, and allyl phenol derivatives is preferable. Specific examples of the thermosetting resin include bismaleimide resin (commercially available as BMI-70 from K-I Chemical Industry Co., Ltd.), allyl phenol resin (commercially available as MEH-8000H from Meiwa Kasei, Co., Ltd.), bis-allyl-nadi-imide resin (commercially available as BAMI-M from Maruzen Petrochemical, Co., Ltd.), and the like.

Any resin can be added to the thermosetting resin layer of the present invention, provided that the resin layer contains a three-dimensional cross-linked thermosetting resin, and a thermoplastic resin is preferably added to impart a film-forming property. Preferably, the thermosetting resin layer contains a solvent-soluble three-dimensional cross-linked thermosetting resin and a solvent-soluble thermoplastic resin. More preferably, the thermosetting resin layer contains a three-dimensional cross-linked thermosetting resin having at least two reactive functional groups in one molecule and a solvent-soluble thermoplastic resin so as to improve the thermostability and film-forming property of the thermosetting resin layer.

A thermoplastic resin contained in the thermoplastic resin layer of the present invention is preferably selected from at least one from the group consisting of polyimide resins, polyamide imide resins, siloxane-modified polyimide resins, polyether imide resins, polyether ketone resins, polyether ether ketone resins, and thermoplastic liquid crystal resins (they are all soluble to solvent), and any thermoplastic resin may be used, provided that the thermoplastic resin has flexibility, tensile strength and tear resistance required for the flexible metal stacked body and is suitable for practical use. At least one solvent-soluble resin selected from the group consisting of polyimide resins, polyamide imide resins, and siloxane-modified polyimide resins are particularly preferable. Any polyimide resins, polyamide imide resins, and siloxane-modified polyimide resins may be used, provided that even when the resin is substantially imidized, the resin is solvent-soluble and can form a film without requiring any other compound. The glass-transition temperature (Tg) of the thermoplastic resin is preferably 200° C. or higher, and more preferably 250° C. or higher, and even more preferably 300° C. or higher. A specific example of the thermoplastic resin is polyamide imide resin (commercially available as VYLOMAX HR16NN from Toyobo, Co., Ltd.; the glass-transition temperature of 300° C.) and the like.

Each of the resin layers in the flexible metal stacked body according to the present invention preferably contains filler having average grain diameter of 5 μm or less. Inorganic or organic fillers may be used as the filler, and the filler is added to at least either the thermosetting resin layer or the thermoplastic resin layer. Alternatively, the filler may preferably be added to only one of the thermosetting resin layer adjacent to the metal layer or a thermosetting resin layer which is not adjacent to the metal layer, a certain thermoplastic resin layer, and the outermost thermosetting or thermoplastic resin layer. The filler can impart a slipping property to the resin surface of the metal stacked body, and can made metal stacked body less susceptible to change in the dimension by reducing liquidization of the resin. Therefore, it is preferable to use filler for an application in which the metal stacked body is required to have slipping property and resistance to dimensional change. The average grain diameter of the filler is preferably 5 μm or less since filler's dispersibility to resin and the film forming property of the resin are deteriorated when the average grain diameter of the filler is more than 5 μm. Although the content of the filler may vary according to the purpose, and the content of the filler is between 0.1% and 70% by weight, preferably is between 0.5% and 60% by weight, and more preferably is between 1% and 50% by weight per the total solid content. If the content of the filler is less than 0.1% by weight, the filler cannot sufficiently impart the slipping property and resistance to dimensional change. If the content of the filler is more than 70% by weight, a sufficient tenacity and ductility cannot be achieved and the film forming property is compromised. As filler, for example, inorganic fillers such as silica, silica powder, alumina, calcium carbonate, magnesium oxide, diamond powder, mica, fluororesins, and zircon are preferably used.

The method of stacking thermosetting resin layers and thermoplastic resin layers above the metal layer cannot be limited. For example, a thermosetting resin layer dissolved in a solvent is coated on a metal layer, e.g., a metal foil, followed by drying out of the solvent, and then a molten thermoplastic resin is staked on the thermosetting resin layer using an extruder. Alternatively, the thermoplastic resin dissolved in a solvent may be staked on the thermosetting resin layer by coating the dissolved thermoplastic resin. The thermosetting resin layer is preferably coated on a metal layer, e.g., a copper foil, by dissolving the thermosetting resin layer in a solvent and coating the thermosetting resin layer on the metal layer, followed by drying out of the solvent since the thermosetting resin may cure, become insoluble and make extruding difficult when the thermosetting resin is melted by heat before extruding it on the metal layer.

Any method of stacking may be used, provided that each resin for forming a resin layer is dissolved in an organic solvent, and is coated using a coater. As a coater for coating a resin above a metal layer, any coater may be used provided that the coater can coat the resin layers to a desired thickness. For example, a dam-type coater, a reverse coater, a lip coater, a microgravure coater, a comma coater may be used. Furthermore, extrusion molding may be used when a resin for forming a resin layer is melted by heat and then is molded. As examples of extrusion molding method, well-known T-die method, laminated body drawing method, or inflation method may be used.

Any method for using solvent may be used for the present invention. The materials for each layer are preferably dissolved in a solvent to use in a coating/stacking step, and any type of solvent may be used. Any commercially available solvent may be used, and an example of a preferable solvent is an aprotic solvent. Specific examples of aprotic solvents include dimethylformamide, dimethylacetamide, N-methyl-2-pyrrolidone, dimethylsulfoxide, nitrobenzene, glycol carbonate and the like. In addition to an aprotic solvent, a solvent which is compatible with the aprotic solvent is suitable for the use. Examples of such solvent include aromatic solvents such as benzene, toluene, xylene; ketenes such as acetone and methyl ethyl ketone; ethers such as tetrahydrofuran, dioxane, 1,2-dimethoxyethane, polyethylene glycol dimethylether, which are preferably used.

### EXAMPLES

Hereinafter, the present invention will be described using examples. It should be noted, however, the present invention is not limited to those specific examples. In the examples, “percent” means percent by weight.

### Preparation of Thermosetting Resin Solution A

Bismaleimide resin (commercially available as BMI-70 from K-I Chemical Industry Co., Ltd) was dissolved in N-methyl-2-pyrrolidone (hereinafter, abbreviated as NMP) to prepare a bismaleimide resin solution of a solid content of 40% and allyl phenol resin (commercially available as MEH-8000H from Meiwa Kasei, Co., Ltd.) was dissolved in NMP to prepare an allyl phenol solution of a solid content of 40%. The bismaleimide resin solution and the allyl phenol solution were mixed in a weight ratio of the bismaleimide resin solution:the allyl phenol solution of 3:1 to prepare a thermosetting resin solution (a). Then the thermosetting resin solution (a) and the thermoplastic resin solution C which will be explained later were mixed in a weight ratio of thermosetting resin solution (a):thermoplastic resin solution C of 6:4 to prepare a thermosetting resin solution A.

### Preparation of Thermosetting Resin Solution B

The thermosetting resin solution (a) used to prepare the thermosetting resin solution A and the thermoplastic resin solution C which will be described later were mixed in a weight ratio of thermosetting resin solution (a):thermoplastic resin solution C of 4:6 to prepare a thermosetting resin solution B.

### Preparation of Thermoplastic Resin Solution C

Polyamide imide resin (commercially available as VYLOMAX HR16NN from Toyobo, Co., Ltd. having a glass-transition temperature of 300° C.) was dissolved in NMP to prepare the thermoplastic resin solution C having a solid content of 14%.

### Formation of Flexible Metal Stacked Body

### Example 1

As a metal layer, an electrolytic copper foil having a thickness of 12 μm (commercially available as TQ-VLP from Mitsui Kinzoku) was used, and the thermosetting resin solution B was coated on the matte side thereof and then dried at 150° C. for 10 minutes to form a B-stage cured first thermosetting resin layer having a thickness of 2 μm. Then, the thermoplastic resin solution C was coated on the surface of the resin layer and then dried at 150° C. for 10 minutes to form a first thermoplastic resin layer having a thickness of 18 μm. On the surface of the first thermoplastic resin layer, a second thermosetting resin layer having a thickness of 2 μm and a second thermoplastic resin layer having a thickness of 18 μm were stacked alternately under the same conditions as the conditions described above, and then, the stacked body was heat cured at 300° C. for 3 hours under a nitrogen atmosphere to obtain a flexible metal stacked body of the present invention.

### Examples 2 to 9

Flexible metal stacked bodies were prepared under the same conditions as Example 1, except that four layers were stacked above the metal layer using the thermosetting resin solution A and the thermosetting resin solution B, and the thermoplastic resin solution C to the thicknesses listed in Table 1. The heat curing condition of the thermosetting resin solution A was the same as that of the thermosetting resin solution B described in Example 1.

### Comparative Example 1

As a metal layer, an electrolytic copper foil having a thickness of 12 μm (commercially available as TQ-VLP from Mitsui Kinzoku) was used, and the thermoplastic resin solution C was coated on the matte side of the electrolytic copper foil and then dried at 150° C. for 10 minutes to form a thermoplastic resin layer (1) having a thickness of 13 μm. Then, the thermosetting resin solution A was coated on the surface of the layer (1) and then dried at 150° C. for 10 minutes to form a B-stage cured first thermosetting resin layer (2) having a thickness of 7 μm. Next, a layer (3) and a layer (4) were stacked by coating the thermoplastic resin solution C on the surface of the layer (2) to form the layer (3) having a thickness of 13 μm, and coating the thermosetting resin solution A on the layer (3) to form the thermosetting resin layer (4) having a thickness of 7 μm under the conditions the same as conditions described above. The stacked body was heat cured at 300° C. for 3 hours under a nitrogen atmosphere to prepare a comparable flexible metal stacked body.

### Comparative Example 2

As a metal layer, an electrolytic copper foil having a thickness of 12 μm (commercially available as TQ-VLP from Mitsui Kinzoku) was used, and the thermosetting resin solution A was coated on the matte side thereof and then dried at 150° C. for 10 minutes to form a B-stage cured first thermosetting resin layer (1) having a thickness of 20 μm. Then, the thermoplastic resin solution C was coated on the surface of the layer (1) and then dried at 150° C. for 10 minutes to form a first thermoplastic resin layer (2) having a thickness of 10 μm. Next, a layer (3) was stacked by coating the thermoplastic resin solution C on the surface of the layer (2) to form the layer (3) made of thermoplastic resin having a thickness of 10 μm. The stacked body was heat cured at 300° C. for 3 hours under a nitrogen atmosphere to prepare a comparable flexible metal stacked body under the conditions the same as conditions described above.

The ratio T_{α}/T_{β} of the flexible metal stacked bodies in Examples 1 to 9 are listed in Table 2.

TABLE 1
Unit: μm

| | | Examples | | | | | | | | |
|---|---|---|---|---|---|---|---|---|---|---|
| | Resin Solution | 1 | 2 | 3 | 4 | 5 | 6 | 7 | 8 | 9 |
| 1st. Thermosetting Resin | Thermosetting Solution A | — | — | 3 | 5 | 7 | 10 | 17 | — | — |
| Layer | Thermosetting Solution B | 2 | 3 | — | — | — | — | — | 10 | 10 |
| 1st. Thermoplastic Resin | Thermoplastic Solution C | 18 | 17 | 17 | 15 | 13 | 10 | 3 | 10 | 20 |
| Layer | | | | | | | | | | |
| 2nd. Thermosetting Resin | Thermosetting Solution A | — | — | 3 | 5 | 7 | 10 | 17 | — | — |
| Layer | Thermosetting Solution B | 2 | 3 | — | — | — | — | — | 10 | 10 |
| 2nd. Thermoplastic Resin | Thermoplastic Solution C | 18 | 17 | 17 | 15 | 13 | 10 | 3 | 10 | — |
| Layer | | | | | | | | | | |

TABLE 2

| | Examples | | | | | | | | |
|---|---|---|---|---|---|---|---|---|---|
| | 1 | 2 | 3 | 4 | 5 | 6 | 7 | 8 | 9 |
| 1st. Thermosetting Resin Layer/ | 0.11 | 0.17 | 0.17 | 0.33 | 0.53 | 1 | 5.66 | 1 | 0.5 |
| 1st. Thermoplastic Resin Layer | | | | | | | | | |
| 2nd. Thermosetting Resin Layer/ | 0.11 | 0.17 | 0.17 | 0.33 | 0.53 | 1 | 5.66 | 1 | — |
| 2nd. Thermoplastic Resin Layer | | | | | | | | | |

Evaluation of Flexible Metal Stacked Body

1. Compression Displacement Measured by TMA

The metal layer of the flexible metal stacked bodies of Examples 1 to 9 and Comparative Examples 1 and 2 were removed by etching using the subtractive method to obtain resin stacked bodies without the metal layer. Then, for each of the resin stacked bodies, TMA penetration was measured using a thermo-mechanical analyzer (TMA7 from PerkinElmer) under the condition described below by pressing the resin sheet from the surface of the resin sheet to which the metal layer had been adhered using the penetration prove having a tip size of 100 μm×100 μm. The results of displacement at 300° C. are listed in Table 3. Measurement conditions were as follows: a load of 1000 mN/cm², rate of temperature rise of 50° C./min, and the environmental condition of normal temperature and normal humidity.

Furthermore, as a metal layer, an electrolytic copper foil having a thickness of 12 μm (commercially available as TQ-VLP from Mitsui Kinzoku) was used, and the thermoplastic resin solution C was coated on the matte side of the electrolytic copper foil and then dried at 150° C. for 10 minutes to form a thermoplastic resin layer. Then, the stacked body was heat cured at 300° C. for 3 hours under a nitrogen atmosphere to obtain a sheet-like flexible metal stacked body having a total thickness of 40 μm. Similarly, an electrolytic copper foil having a thickness of 12 μm (commercially available as TQ-VLP from Mitsui Kinzoku) was used, and the thermosetting resin solution A was coated on the matte side thereof and then dried at 150° C. for 10 minutes to form a B-stage cured thermosetting resin layer. Then, the stacked body was heat cured at 300° C. for 3 hours under a nitrogen atmosphere to obtain a sheet-like flexible metal stacked body having a total thickness of 40 μm. Furthermore, a sheet-like flexible metal stacked body having a total thickness of 40 μm was obtained in the method similar to the described above except that thermosetting resin solution B was used in place of thermosetting resin solution A. The metal layers of the sheet-like flexible metal stacked bodies described above were removed by etching using a subtractive method. Then, for each of the resin stacked bodies, TMA penetration was measured by pressing the resin sheets from the surface of the resin sheet to which the metal layer had been adhered, under the same conditions described above. The results of displacement at 300° C. are listed in Table 4.

2. Elastic Modulus (E′)

For the resin sheets only made of the thermoplastic resin C, the resin sheet only made of the thermosetting resin A, and the resin sheet only made of the thermosetting resin B which were used for the measurement of the penetration by TMA, the elastic modulus (E′) at 350° C. were measured using a compulsion vibration dissonance viscoelasticity tester (Rheovibron from Orientech Co., Tokyo, Japan) under the following conditions: the vibration frequency of 11 MHz, static tension of 3.0 gf, sample size of 0.5 mm (width)×30 mm (length), and the rate of temperature rise of 10° C./min, and the environmental conditions of normal temperature and normal humidity. The results are listed in Table 4.

TABLE 3

| | | | | | | | | | | Comparative | |
|---|---|---|---|---|---|---|---|---|---|---|---|
| | Examples | | | | | | | | | Examples | |
| | 1 | 2 | 3 | 4 | 5 | 6 | 7 | 8 | 9 | 1 | 2 |
| TMA Compression | 11 | 10 | 10 | 5 | 5 | 4 | 4 | 5 | 8 | 12 | 12 |
| Displacement | | | | | | | | | | | |
| (μm) | | | | | | | | | | | |

TABLE 4

| | Thermosetting | Thermosetting | Thermoplastic |
|---|---|---|---|
| | resin | resin | resin |
| | from | from | from |
| | solution A | solution B | solution C |
| TMA | 4 | 6 | 12 |
| Compression | | | |
| Displacement | | | |
| (μm) | | | |
| Elastic | 710 | 590 | 70 |
| Modulus | | | |
| (E′) | | | |
| (MPa) | | | |

3. Curl

The flexible metal stacked bodies of the Examples 1 to 9 and Comparative Examples 1 and 2 were cut into a small piece of a size of 70 mm×70 mm. Then, the cut samples were moisture conditioned in a thermo-hygrostat which were adjusted to a temperature of 23° C. and a humidity of 55% for 72 hours, and the pieces were placed on a smooth glass plate with the surface facing upward, and the height of the curled samples from the glass surface were measured. The results are listed in Table 5.

4. Thermostability

The metal layer of the flexible metal stacked bodies of the Examples 1 to 9 and Comparative Examples 1 and 2 were etched using a subtractive method to define a circuit pattern for flip-chip bonding. After the samples were moisture conditioned in a thermo-hygrostat which were adjusted to a temperature of 23° C. and a humidity of 55% for 72 hours. Then the samples were flip-chip bonded using a flip-chip bonder (Shibuya Kogyo, Co., Ltd.). The change in appearance and the cross-section of the bonded area were observed based on the following criteria: maximum temperature of 450° C., duration of the maximum temperature of 2.5 seconds, and load of 100 N/cm². The results are listed in Table 5.

Evaluation Criteria

E: No change in appearance, and no significant deformation or peeling-off of the bonded area

G: No change in appearance and peeling-off, but deformation of the bonded area is present

P: Appearance is changed and significant deformation of bonded area, and peeling-off and breakage of the metal layer are observed

TABLE 5

| | | | | | | | | | | Comparative | |
|---|---|---|---|---|---|---|---|---|---|---|---|
| | Examples | | | | | | | | | Examples | |
| | 1 | 2 | 3 | 4 | 5 | 6 | 7 | 8 | 9 | 1 | 2 |
| Curl | 0.5 | 2.1 | 2.3 | 2.7 | 3.2 | 4.4 | 17.2 | 15.6 | 19.8 | 25.3 | 24.7 |
| (μm) | | | | | | | | | | | |
| Thermostability | G | G | G | E | E | E | E | E | E | P | P |

As is apparent from the results in Table 5, the present invention (Examples 1 to 9) exhibited a stronger effect of improving thermo stability of the flip-chip bonding compared to a stacked body in which a thermoplastic resin layer is provided adjacent to a metal layer, like Comparative Example 1. This is probably due to the thermosetting resin layer adjacent to the metal layer helping to maintain a high modulus of elasticity and excellent thermostability at temperatures higher than the glass transition temperature of the thermoplastic resin. Furthermore, in Examples 1 to 9, thermostability was improved compared to Comparative Example 2 even though the thermosetting resin layer was provided adjacent to the metal layer in Comparative Example 2 similar to Examples 1 to 9. This indicates that in a metal stacked body in which only a single layer of thermosetting resin layer was provided adjacent to the metal layer, the effect of reducing deformation of the thermoplastic resin layer due to melting or liquidization, and the effect of improving thermostability are not sufficient. In other words, as is evident from the results of Examples 1 to 9, deformation of the thermoplastic resin layer due to melting or liquidization can be reduced while improving the thermostability by alternately stacking thermosetting resin layers. Especially in Examples 4 to 6, it is shown that curl was reduced while improving the thermostability. It is considered that the stress between the metal layer and the resin layer, and between each of the resin layers were distributed by providing the thermosetting resin layer which has a high elastic modulus at 350° C. and exhibits a low TMA penetration at 300° C. adjacent to the metal layer, and by alternately stacking one or more thermoplastic resin layers and one or more thermosetting resin layers above this thermosetting resin layer while optimizing thickness and the ratio of thickness of each layer. As a result, both improvement of thermostability and low curl characteristic were realized, and the stacked body had suitable characteristics for flexible printed circuit boards. In contrast, significant deformation or peeling-off of the bonded area were observed in Comparative Example 1 and 2 compared to Examples 1 to 9, and the thermostability required for the flip-chip bonding was not retained. Thus, transportation and handling of the stacked bodies of Comparative Examples during circuit formation and bonding may be problematic.

The flexible metal stacked body according to the present invention is suitable for the use in a semiconductor integrated circuit (IC) which comprises an insulating layer and a conductor circuit, and is quite useful.

While preferred embodiments of the invention have been described and illustrated above, it should be understood that these are examples of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A flexible metal stacked body comprising:
a metal layer; and
a resin stacked body formed on the metal layer,
wherein the resin stacked body comprises at least one thermosetting resin layer and at least one thermoplastic resin layer, one of the at least one thermosetting resin layer is provided adjacent to the metal layer, and the at least one thermosetting resin layer and the at least one thermoplastic resin layer are stacked alternately.

2. The flexible metal stacked body according to claim 1, wherein T_{α}/T_{β} is in the range from 0.15 to 1 when T_{α} is a thickness of the thermosetting resin layer adjacent to the metal layer and T_{β} is a thickness of the thermoplastic resin layer adjacent to the thermosetting resin layer which is adjacent to the metal layer.

3. The flexible metal stacked body according to claim 1, wherein a penetration of the resin stacked body measured using a thermo-mechanical analyzer is 10 μm or less.

4. The flexible metal stacked body according to claim 1, wherein a penetration of the at least one thermosetting resin layer measured using a thermo-mechanical analyzer is 5 μm or less, and is equal to or less than a penetration of the at least one thermoplastic resin layer measured using a thermo-mechanical analyzer.

5. The flexible metal stacked body according to claim 1, wherein an elastic modulus (E′) of the at least one thermosetting resin layer at 350° C. is higher than an elastic modulus (E′) of the at least one thermoplastic resin layer at 350° C. by 200 MPa.

6. The flexible metal stacked body according to claim 1, wherein the at least one thermosetting resin layer contains at least one selected from the group consisting of maleimide derivatives, bis-allyl-nadi-imide derivatives, and allyl phenol derivatives.

7. The flexible metal stacked body according to claim 1, wherein the at least one thermosetting resin layer contains a solvent-soluble three-dimensional cross-linked thermosetting resin having at least two reactive functional groups in one molecule and a solvent-soluble thermoplastic resin.

8. The flexible metal stacked body according to claim 1, wherein the at least one thermoplastic resin layer contains at least one solvent-soluble resin selected from the group consisting of polyimide resins, polyamide imide resins, and siloxane-modified polyimide resins.

9. The flexible metal stacked body according to claim 1, wherein the at least one thermoplastic resin layer has a glass transition temperature of 200° C. or higher.

10. The flexible metal stacked body according to claim 1, wherein the metal layer is one metal foil selected from the group consisting of a copper foil, a stainless steel foil, an aluminum foil, and a steel foil.
